(19) United States
(12) Patent Application Publication
(10) Pub. No.: US 2026/0080928 A1
(43) Pub. Date: Mar. 19, 2026

(54) SEMICONDUCTOR STORAGE DEVICE

(71) Applicant: Kioxia Corporation, Tokyo (JP)

(72) Inventors: Takeshi AOKI, Ebina Kanagawa (JP); Tsuneo INABA, Kamakura Kanagawa (JP); Takayuki MIYAZAKI, Setagaya Tokyo (JP)

(73) Assignee: Kioxia Corporation, Tokyo (JP)

(21) Appl. No.: 19/079,009

(22) Filed: Mar. 13, 2025

(30) Foreign Application Priority Data
Sep. 13, 2024 (JP) 2024-159588

(51) Int. Cl. G11C 11/405

(52) U.S. Cl. CPC G11C 11/405

(57) ABSTRACT

A semiconductor storage device according to the present embodiment includes a plurality of first data lines and a plurality of first control lines to be used for writing of data, a plurality of second data lines and a plurality of second control lines to be used for reading of data, and a plurality of memory cells. A first drive line is provided in common to the first control lines and the second control lines and transmits a selection voltage for performing writing of data. A plurality of fourth transistors are connected between the first control lines and the first drive line. A plurality of fifth transistors are connected between the second control lines and the first drive line. A plurality of third control lines are connected to gates of the fourth transistors, respectively. A plurality of fourth control lines are connected to gates of the fifth transistors, respectively.

### CROSS REFERENCE TO RELATED APPLICATIONS

This application is based upon and claims the benefit of priority from the prior Japanese Patent Application No. 2024-159588, filed on September 13, 2024, the entire contents of which are incorporated herein by reference.

### FIELD

The embodiments of the present invention relate to a semiconductor storage device.

### BACKGROUND

A gain cell memory reads data by amplifying accumulated charges in a sense node using a transistor. In a gain cell memory, a reading port and a writing port are separately provided and bit lines and word lines are provided for each of reading and writing. Therefore, the number of lines is large and the wiring structure is complicated. Furthermore, with increase in the number of lines, the number of drivers is also increased and power consumption is increased.

### BRIEF DESCRIPTION OF THE DRAWINGS

FIG. 1 is a circuit diagram illustrating a configuration example of a single memory cell according to a first embodiment;

FIG. 2 is a perspective view illustrating a configuration example a gain cell memory according to the first embodiment;

FIG. 3 is a conceptual diagram illustrating a read operation of the gain cell memory according to the first embodiment;

FIG. 4 is a timing chart illustrating an operation example of the gain cell memory according to the first embodiment;

FIG. 5 is a perspective view illustrating a configuration example of a gain cell memory according to a second embodiment;

FIG. 6 is a conceptual diagram illustrating a read operation of the gain cell memory according to the second embodiment;

FIG. 7 is a perspective view illustrating a configuration example of a gain cell memory according to a third embodiment;

FIG. 8 is a perspective view illustrating a configuration example of a gain cell memory according to a fourth embodiment; and

FIG. 9 is a perspective view illustrating a configuration example of a gain cell memory according to a fifth embodiment.

### DETAILED DESCRIPTION

In general, according to the embodiment, a semiconductor storage device comprises: a plurality of first data lines and a plurality of first control lines to be used for writing of data; and a plurality of second data lines and a plurality of second control lines to be used for reading of data. A plurality of memory cells each comprises a first transistor having a gate connected to any of the first control lines and one end connected to any of the first data lines, a second transistor having a gate connected to any of the second control lines and one end connected to any of the second data lines, and a third transistor having a gate connected to the other end of the first transistor to retain data from the first data line and one end connected to the other end of the second transistor. The third transistor is brought to a conduction state according to the data. A first drive line is provided in common to the first control lines and the second control lines and transmits a selection voltage for performing writing of data. A plurality of fourth transistors are connected between the first control lines and the first drive line. A plurality of fifth transistors are connected between the second control lines and the first drive line. A plurality of third control lines are connected to gates of the fourth transistors, respectively. A plurality of fourth control lines are connected to gates of the fifth transistors, respectively. Hereinafter, devices of the present disclosure will be described with reference to the drawings.

The present invention is not limited to the embodiments. In the present specification and the drawings, elements identical to those described in the foregoing drawings are denoted by like reference characters and detailed explanations thereof are omitted as appropriate.

### First embodiment

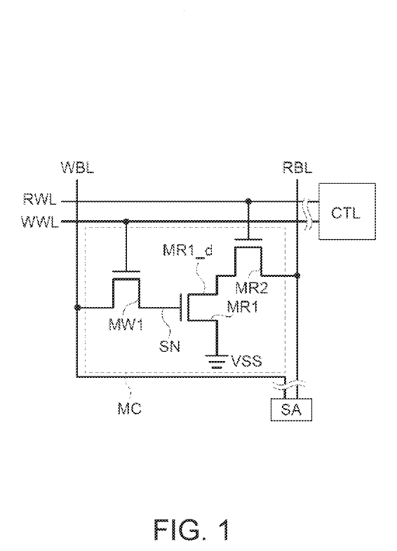

FIG. 1 is a circuit diagram illustrating a configuration example of a single memory cell according to a first embodiment. A memory cell MC of a gain cell memory is constituted of three transistors MW1, MR1, and MR2. Each of the transistors MW1, MR1, and MR2 is constituted of, for example, an n-type OSFET (Oxide Semiconductor Field Effect Transistor).

The gate of the transistor MW1 as a first transistor is connected to a write word line WWL as a first control line. One electrode of the transistor MW1 is connected to a write bit line WBL as a first data line. The other electrode of the transistor MW1 is connected to the gate of the transistor MR1. One electrode and the other electrode of the transistor MW1 function as a source electrode or a drain electrode according to a voltage supplied to the transistor MW1. The transistor MW1 connects the write bit line WBL to the gate (hereinafter, also "sense node SN") of the transistor MR1, which functions as a sense node SN under control of the write word line WWL. The transistor MW1 transmits a voltage of the write bit line WBL to the sense node SN when in a conduction state (an on-state). The transistor MW1 holds a voltage of the sense node SN when in a non-conduction state (an off-state). In this way, the transistor MW1 can write a voltage (data) from the write bit line WBL to the sense node SN or can cause a written voltage (data) to be retained in the sense node SN.

The gate of the transistor MR1 as a third transistor is connected to the other electrode of the transistor MW1 and functions as a sense node SN. One electrode (for example, the source) of the transistor MR1 is connected to a low-voltage source VSS. The other electrode (for example, the drain) of the transistor MR1 is connected to one electrode of the transistor MR2. The transistor MR1 is brought to a conduction state according to a voltage (that is, data) of the sense node SN. For example, when the sense node SN is kept at a high-level voltage (for example, data "1"), the transistor MR1 is brought to an on-state. When the sense node SN is kept at a low-level voltage (for example, data "0"), the transistor MR1 is brought to an off-state.

The gate of the transistor MR2 as a second transistor is connected to a read word line RWL as a second control line. One electrode of the transistor MR2 is connected to the drain of the transistor MR1. The other electrode of the transistor MR2 is connected to a read bit line RBL as a second data line. One electrode and the other electrode of the transistor MR2 can function as a source electrode or a drain electrode according to a voltage supplied to the transistor MR2. The transistor MR2 connects the read bit line RWL to the drain of the transistor MR1 under control of the read word line RWL. The transistor MR1 is in a state (the on-state or the off-state) according to a voltage (data) retained in the sense node SN. When the transistor MR2 connects the read bit line RBL to the transistor MR1 at a time of the on-state, charges from the read bit line RBL flow to the low-voltage source VSS according to a state of the transistor MR1. When the transistor MR1 is in the on-state, the charges from the read bit line RBL flow to the low-voltage source VSS and the voltage of the read bit line RBL lowers. When the transistor MR1 is in the off-state, few charges flow from the read bit line RBL to the low-voltage source VSS and the voltage of the read bit line RBL is kept high. Accordingly, a voltage based on data retained in the sense node SN is transmitted to the read bit line RBL.

A sense amplifier SA as a detection circuit is connected to the write bit line WBL and the read bit line RBL. The sense amplifier SA latches write data from outside and applies a voltage according to the write data to the write bit line WBL. The sense amplifier SA detects read data on the basis of a voltage of the read bit line RBL and latches the read data. The read data latched by the sense simplifier SA is transmitted to outside. The sense amplifier SA also performs precharging of the write bit line WBL and the read bit line RBL.

A controller CTL is connected to the write word line WWL and the read word line RWL and controls voltages of the write word line WWL and the read word line RWL.

The write word line WWL and the write bit line WBL are lines to be used for writing of data. The read word line RWL and the read bit line RBL are lines to be used for reading of data. In this way, a gain cell memory uses word lines and bit lines differing between a data write operation and a data read operation. This enables a gain cell memory to read data while maintaining data in a sense node SN (non-destructive read). One memory cell MC is constituted of the three transistors MW1, MR1, and MR2 and does not have a capacitor that is difficult to downscale as that in a DRAM (Dynamic Random Access Memory). Therefore, a gain cell memory is superior in downscaling.

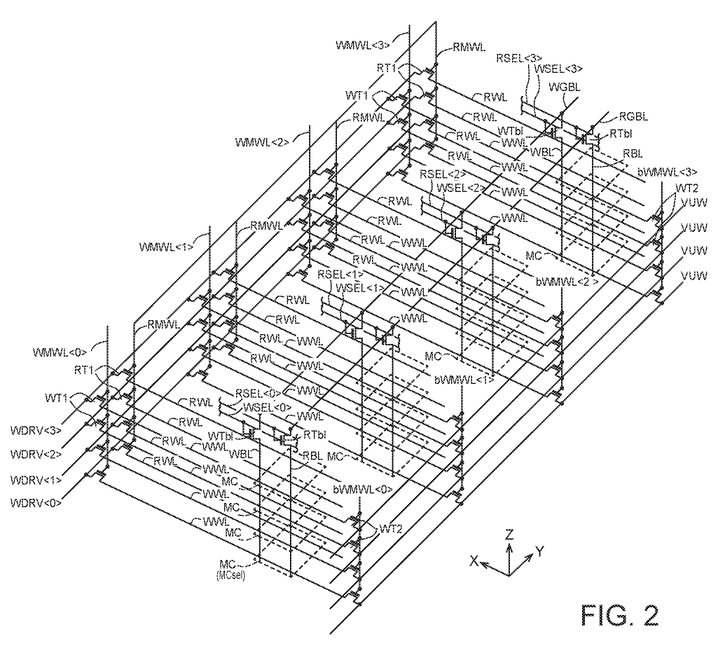

FIG. 2 is a perspective view illustrating a configuration example the gain cell memory according to the first embodiment. The gain cell memory according to the present embodiment includes a three-dimensional memory cell array where a plurality of the memory cells MC are arrayed three-dimensionally. The memory cells MC are arrayed in a matrix including a plurality of rows and a plurality of columns. A row is an array of the memory cells MC in an X direction. A column is an array of the memory cells MC in a Z direction. Furthermore, matrixes of the memory cells MC are arrayed in a Y direction. Accordingly, a memory cell array MCA is a three-dimensional array where the memory cells MC are arrayed three-dimensionally. The number of rows, the number of columns, and the number of matrixes of the memory cells MC are not particularly limited to the illustrated example.

A plurality of write word lines WWL as a plurality of first control lines are provided corresponding to a plurality of rows of memory cells MC, respectively. A plurality of read word lines RWL as a plurality of second control lines are also provided corresponding to the rows of the memory cells MC, respectively. The write word lines WWL are used for writing of data and extend in the X direction. The read word lines RWL are used for reading of data and extend in the X direction.

Each drive line WDRV as a first drive line is provided in common to a plurality of write word lines WWL and a plurality of read word lines RWL arrayed in the Y direction. The drive line WDRV transmits a selection voltage for performing writing of data. A plurality of the drive lines WDRV each extend in the Y direction and are arrayed in the Z direction.

A plurality of transistors WT1 as a plurality of fourth transistors are connected between a plurality of write word lines WWL and an associated drive line WDRV, respectively. One electrodes of the transistors WT1 are connected to the write word lines WWL, respectively. The other electrodes of a plurality of transistors WT1 arrayed in the Y direction are connected in common to one drive line WDRV. One electrode and the other electrode of each of the transistors WT1, and transistors RT1, WT2, WTb1, and RTb1 can function as a source electrode or a drain electrode according to a voltage supplied to the transistors WT1, RT1, WT2, WTb1, and RTb1.

A plurality of transistors RT1 as a plurality of fifth transistors are connected between a plurality of read word lines RWL and an associated drive line WDRV, respectively. One electrodes of the transistors RT1 are connected to the read word lines RWL, respectively. The other electrodes of a plurality of transistors RT1 arrayed in the Y direction are connected in common to one drive line WDRV. The transistors WT1 and RT1 arrayed in the Y direction are connected in common to one drive line WDRV.

Each write main word line WMWL as a third control line is connected in common to the gates of a plurality of transistors WT1 arrayed in the Z direction. That is, each write main word line WMWL is provided in common to a plurality of write word lines WWL arrayed in the Z direction. A plurality of write main word lines WMWL each extend in the Z direction and are arrayed in the Y direction. Each of the write main word lines WMWL selectively brings the transistors WT1 connected thereto to the on-state and connects the drive lines WDRV to the corresponding write word lines WWL, respectively. The write main word lines WMWL arrayed in the Y direction are driven independently of each other. Therefore, the transistors WT1 illustrated in FIG. 2 are controlled to the on-state or the off-state with respect to each plurality of rows arrayed in the Z direction.

Each read main word line RMWL as a fourth control line is connected in common to the gates of a plurality of transistors RT1 arrayed in the Z direction. That is, each read main word line RMWL is provided in common to a plurality of read word lines RWL arrayed in the Z direction. A plurality of read main word lines RMWL each extend in the Z direction and are arrayed in the Y direction. The read main word lines RMWL are connected in common to each other and bring a plurality of transistors RT1 corresponding thereto to the on-state to connect the drive lines WDRV to the read word lines RWL arrayed in the Z direction and the Y direction. A plurality of read main word lines RMWL arrayed in the Y direction are connected in common to each other and are simultaneously driven. Therefore, the transistors RT1 arrayed in the Y and Z directions illustrated in FIG. 2 are controlled to the on-state or the off-state at the same time.

Each write-pass voltage line VUW as a second drive line is provided in common to a plurality of write word lines WWL arrayed in the Y direction. The write-pass voltage line VUW transmits a non-selection voltage for not performing writing of data. A plurality of write-pass voltage lines VUW each extend in the Y direction and are arrayed in the Z direction.

A plurality of transistors WT2 as a plurality of seventh transistors are connected between a plurality of write word lines WWL and an associated write-pass voltage line VUW, respectively. One electrodes of the transistors WT2 are connected to the write word lines WWL, respectively. The other electrodes of a plurality of transistors WT2 arrayed in the Y direction are connected in common to one write-pass voltage line VUW. Meanwhile, the read word lines RWL are electrically separated from the write-pass voltage lines VUW. When the non-selection voltage is fixed, the write-pass voltage lines VUW may be short-circuited with each other as one drive line.

Each non-selection main word line bWMWL is connected in common to a plurality of transistors WT2 arrayed in the Z direction. A plurality of non-selection main word lines bWMWL each extend in the Z direction and are arrayed in the Y direction. The non-selection main word lines bWMWL bring transistors WT2 connected to write word lines WWL corresponding to memory cells MC to which data is not to be written to the on-state to connect the associated write-pass voltage lines VUW to the write word lines WWL, respectively.

A plurality of write bit lines WBL as a plurality of first data lines are provided corresponding to a plurality of columns of memory cells MC, respectively. A plurality of read bit lines RBL as a plurality of second data lines are also provided corresponding to the columns of the memory cells MC, respectively. In FIG. 2, only one write bit line WBL and one read bit line RBL are illustrated. The write bit lines WBL are used for writing of data and extend in the Z direction. The read bit lines RBL are used for reading of data and extend in the Z direction. The read bit lines RBL, the write bit lines WBL, the write main word lines WMWL, the read main word lines RMWL, and the non-selection main word lines bWMWL extend in the Z direction.

Each write global bit line WGBL as a third data line is provided in common to a plurality of write bit lines WBL arrayed in the Y direction. A plurality of write global bit lines WGBL each extend in the Y direction and are arrayed in the X direction. In FIG. 2, only one write global bit line WGBL is illustrated. Each of the write global bit lines WGBL is connected to a write bit line WBL selected from the corresponding write bit lines WBL to transmit data from the sense amplifier SA to the selected write bit line WBL.

Each read global bit line RGBL as a fourth data line is provided in common to a plurality of read bit lines RBL arrayed in the Y direction. A plurality of read global bit lines RGBL each extend in the Y direction and are arrayed in the X direction. In FIG. 2, only one read global bit line RGBL is illustrated. Each of the read global bit lines RGBL is connected to a read bit line RBL selected from the corresponding read bit lines RBL to transmit data from the selected read bit line RBL to the sense amplifier SA.

A plurality of transistors WTb1 are connected between a plurality of write bit lines WBL and an associated write global bit line WGBL, respectively. One electrodes of the transistors WTb1 are connected to the write bit lines WBL, respectively. The other electrodes of a plurality of transistors WTb1 arrayed in the Y direction are connected in common to one write global bit line WGBL. The gates of a plurality of transistors WTb1 arrayed in the X direction are connected in common to an associated write selection line WSEL. A plurality of write selection lines WSEL each extend in the X direction and are arrayed in the Y direction.

In a write operation, one of the write selection lines WSEL is selectively driven. A plurality of transistors WTb1 connected to the selected write selection line WSEL are brought to the on-state and each electrically connect between the corresponding write bit line WBL and the corresponding write global bit line WGBL. Accordingly, the transistors WTb1 connected to the selected write selection line WSEL each transmit data from the sense amplifier SA, from the corresponding write global bit lines WGBL to the corresponding write bit lines WBL, respectively.

Considering the capacity of each write bit line WBL, it is preferable that the transistors WTb1 are provided for a high-speed operation of the write bit lines WBL. However, when the operation speed is not considered, it is possible that the transistors WTb1 are not provided.

A plurality of transistors RTb1 as a plurality of sixth transistors are connected between a plurality of read bit lines RBL and an associated read global bit line RGBL, respectively. One electrodes of the transistors RTb1 are connected to the read bit lines RBL, respectively. The other electrodes of a plurality of transistors RTb1 arrayed in the Y direction are connected in common to one read global bit line RGBL. The gates of a plurality of transistors RTb1 arrayed in the X direction are connected in common to an associated read selection line RSEL. A plurality of read selection lines RSEL each extend in the X direction and are arrayed in the Y direction.

In a read operation, one of the read selection lines RSEL is selectively driven. A plurality of transistors RTb1 connected to the selected read selection line RSEL are brought to the on-state and each electrically connect between the corresponding read bit line RBL and the corresponding the read global bit line RGBL. Accordingly, the transistors RTb1 connected to the selected read selection line RSEL each transmit data from the associated memory cells MC, from the corresponding read bit lines RBL to the corresponding read global bit lines RGBL, respectively.

A plurality of memory cells MC are provided corresponding to intersecting portions between a pair of a write word line WWL and a read word line RWL adjacent to each other in the Y direction and a pair of a write bit line WBL and a read bit line RBL adjacent to each other in the X direction, respectively. Therefore, the memory according to the present embodiment can write data to one memory cell MC by selecting one write word line WWL and one write bit line WBL at the time of writing. At the time of reading, the memory can read data from one memory cell MC by selecting one read word line RWL and one read bit line RBL.

A layer including a plurality of write word lines WWL, a plurality of read word lines RWL, and a plurality of memory cells MC corresponding to one drive line WDRV is assumed as a set. In this case, one write main word line WMWL is connected in common to the gates of a plurality of transistors WT1 corresponding to a plurality of sets. One read main word line RMWL is connected in common to the gates of a plurality of transistors RT1 corresponding to a plurality of sets. One non-selection main word line bWMWL is connected in common to the gates of a plurality of transistors WT2 corresponding to a plurality of sets. One write main word line WMWL is provided in common to a plurality of write word lines WWL corresponding to a plurality of sets. One read main word line RMWL is provided in common to a plurality of read word lines RWL corresponding to a plurality of sets.

One end of each of the write word lines WWL is connected to a drive line WDRV via a transistor WT1, and the other end thereof is connected to a write-pass voltage line VUW via a transistor WT2. Meanwhile, one end of each of the read word lines RWL is connected to a drive line WDRV via a transistor RT1 and the other end thereof is not connected to a transistor, a drive line, or the like.

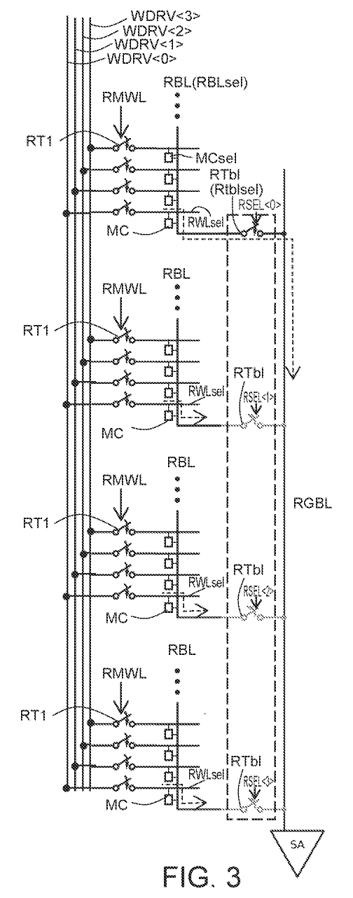

FIG. 3 is a conceptual diagram illustrating a read operation of the gain cell memory according to the first embodiment. In FIG. 3, a configuration related to one read global bit line RGBL associated with a read operation is extracted and illustrated. Practically, a plurality of read global bit lines RGBL arrayed in the X direction simultaneously transmit data from memory cells MC corresponding thereto, respectively. The read operation is explained below with reference to FIGS. 2 and 3.

In the read operation, each of read main word lines RMWL is caused to rise and a plurality of transistors RT1 sharing the read main word line RMWL are brought to the on-state. In FIGS. 2 and 3, all the transistors RT1 are brought to the on-state and each of drive lines WDRV<0> to WDRV<3> is connected to a plurality of read word lines RWL of a set (layer) corresponding thereto.

The controller CTL selectively drives one drive line WDRV (for example, WDRV<0>) from among the drive lines WDRV. Accordingly, one set (for example, the lowermost layer in FIG. 2) corresponding to the selected drive line WDRV<0> is selected. That is, a high-level voltage for read is applied to read word lines RWLsel in the lowermost layer connected to the drive line WDRV<0>. Accordingly, data in memory cells MC connected to the read word lines RWLsel in the lowermost layer in FIG. 2 are transmitted to read bit lines RBL corresponding thereto, respectively.

The controller CTL also selects one read selection line RSEL among the read selection lines RSEL illustrated in FIG. 2 and brings a plurality of transistors RTb1 connected to the selected read selection line RSEL to the on-state. Accordingly, a plurality of read bit lines RBL corresponding to the selected read selection line RSEL are connected to the corresponding read global bit lines RGBL, respectively. Therefore, data in selected memory cells MCsel of a plurality of columns are transmitted through the read global bit lines RGBL corresponding thereto, and are detected by a plurality of sense amplifiers SA, respectively.

FIG. 3 illustrates one selected read bit line RBLsel, and one read global bit line RGBL corresponding thereto, and the like. Therefore, in FIG. 3, one read bit line RBLsel selected from the read bit lines RBL is connected to one read global bit line RGBL. Accordingly, data in a selected memory cell MCsel is transmitted through the read global bit line RGBL and is detected by the sense amplifier SA.

Meanwhile, in FIG. 3, while non-selected read bit lines RBL other than the read bit line RBLsel transmit data in the memory cells MC, the transistors RTb1 corresponding thereto are in the off-state. Therefore, the data transmitted to the non-selected read bit lines RBL other than the read bit line RBLsel are not transmitted to the read global bit line RGBL and collision of data does not occur. The gain cell memory can perform non-destructive read of data. Accordingly, there is no problem even if data in memory cells MC are transmitted to non-selected read bit lines RBL.

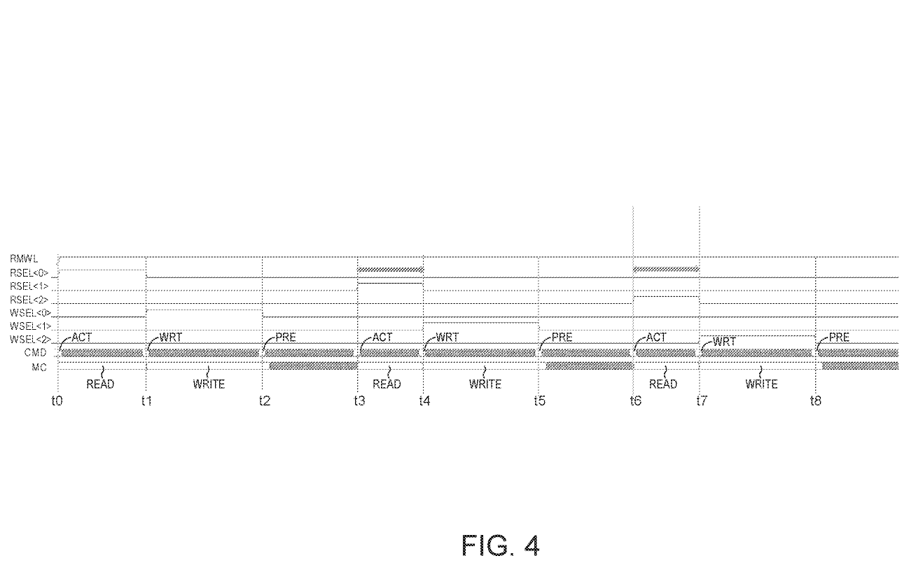

FIG. 4 is a timing chart illustrating an operation example of the gain cell memory according to the first embodiment. A write operation is illustrated in FIG. 4. In the write operation, the controller CTL once reads out data to a sense amplifier SA, and the sense amplifier SA updates the data and then rewrites the updated data to a memory cell MC. It is assumed that the drive line WDRV<0> is selectively driven in this example.

For example, upon reception of an active command ACT as a command CMD at t0, the controller CTL causes the read main word lines RMWL to rise. Therefore, the selected drive line (for example, WDRV<0>) is connected to the read word lines RWL of the corresponding set (for example, the lowermost layer). Data in memory cells MC corresponding to the selected drive line are read out to the associated read bit lines RBL, respectively. At this time, all read bit lines RBL included in the selected set transmit the data in the memory cells MC to just before the associated transistors RTb1, respectively.

At t0, a read selection line RSEL<0> is caused to rise. Accordingly, the controller CTL drives a plurality of transistors RTb1 connected to the same read selection line RSEL<0> (arrayed in the X direction (the row direction) in FIG. 2) at the same timing. A plurality of read bit lines RBL in columns connected to the read selection line RSEL<0> transmit the data to the read global bit lines RGBL, respectively.

Next, the data are updated by the corresponding sense amplifiers SA.

Subsequently, upon reception of a write command WRT at t1, the controller CTL causes a write selection line WSEL<0> to rise. Accordingly, the controller CTL transmits the data to a plurality of write bit lines WBL connected to the write selection line WSEL<0> and writes the data to the memory cells MC in the selected set. Therefore, the data are written to the same memory cells MC sharing the read selection line RSEL<0> and the write selection line WSEL<0> in the selected set (for example, the lowermost layer).

Upon reception of a precharge command PRE at t2, the controller CTL precharges the read bit lines RBL, the write bit lines WBL, and the like.

Similarly, at t3 to t5, the controller CTL causes a read selection line RSEL<1> to rise and subsequently causes a write selection line WSEL<1> to rise while the read main word lines RMWL are kept risen. Accordingly, the controller CTL once reads data from memory cells MC sharing the read selection line RSEL<1> and the write selection line WSEL<1> in the selected set and writes data to the same memory cells MC.

Similarly, at t6 to t8, the controller CTL causes a read selection line RSEL<2> to rise and subsequently causes a write selection line WSEL<2> to rise while the read main word lines RMWL are kept risen. Accordingly, the controller CTL once reads data from memory cells MC sharing the read selection line RSEL<2> and the write selection line WSEL<2> in the selected set and writes data to the same memory cells MC.

To generalize the process, the controller CTL causes a read selection line RSEL<i> (i is an integer equal to or more than zero) to rise and subsequently causes a write selection line WSEL<i> to rise while the read main word lines RMWL are kept risen. This enables the controller CTL to once read data from memory cells MC sharing the read selection line RSEL<i> and the write selection line WSEL<i> in a selected set and to write data to the same memory cells MC.

As described above, the controller CTL can cause a read selection line RSEL<i> and a write selection line WSEL<i> to sequentially and continuously rise while the read main word lines RMWL are kept risen. This eliminates the need to cause the read main word lines RMWL to rise at each rising of a read selection line RSEL and a write selection line WSEL and can shorten the time required to cause the read main word lines RMWL to rise. The order of rising of the read selection line RSEL<i> and the write selection line WSEL<i> is not limited to the example described above and other orders may be applicable.

In a read operation, although the write operations (for example, at t1 to t2, t4 to t5, and t7 to t8) in FIG. 4 are omitted, the rest of the operation is same as that illustrated in FIG. 4. Therefore, also in the read operation, it is unnecessary to cause the read main word lines RMWL to rise at each rising of a read selection line RSEL and the time required to cause the read main word lines RMWL to rise can be shortened.

As described above in the present embodiment, the controller CTL selects one set (for example, the lowermost layer in FIG. 2) by selectively driving one drive line (for example, WDRV<0>). At this time, the read bit lines RBL transmit data from a plurality of memory cells MC in this selected set, respectively. Furthermore, the controller CTL selects one read selection line RSEL and brings a plurality of transistors RTb1 corresponding to one read word line RWL in the selected set to the on-state. Accordingly, data are transmitted from the read bit lines RBL corresponding to one read word line RWL in the selected set to the corresponding read global bit lines RGBL, respectively. Therefore, even when the other end of each of the read word lines RWL is not connected to a transistor, a drive line, or the like, the read global bit lines RGBL can transmit data from selected memory cells MC, respectively.

Furthermore, according to the present embodiment, each of the drive lines WDRV is shared by write word lines WWL and read word lines RWL. The read main word lines RMWL are also shared thereby. Any read-pass word line or any transistor is not provided at the other end of each of the read word lines RWL. Accordingly, the wiring can be simplified while non-destructive read is possible. With the simplification of the wiring, the number of drivers that drive the voltages of lines is reduced and power consumption can be also decreased.

In the present embodiment, since the read main word lines RMWL are shared, selection of a read word line RWL is enabled by selection of a read bit line RBL connecting to a read global bit line RGBL. In this case, when many row addresses for selecting a plurality of adjacent read word lines RWL are issued, selection of a read bit line RBL suffices without driving of the adjacent read word lines RWL. This can decrease the proximity effect of the read word lines RWL.

### Second embodiment

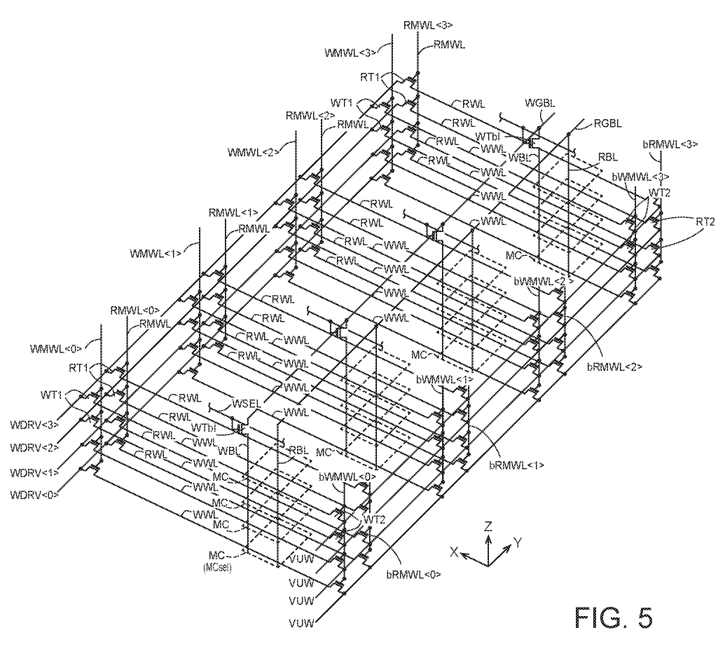

FIG. 5 is a perspective view illustrating a configuration example of a gain cell memory according to a second embodiment. According to the second embodiment, each of the read global bit lines RGBL is connected in common to the read bit lines RBL corresponding thereto. The transistor RTb1 is not provided between each of the read bit lines RBL and the corresponding read global bit line RGBL.

Meanwhile, a plurality of transistors RT2 as a plurality of eighth transistors are connected between a plurality of read word lines RWL and an associated write-pass voltage line VUW, respectively. That is, the other ends of the read word lines RWL are connected to the associated write-pass voltage line VUW via the transistors RT2, respectively. One electrodes of the transistors RT2 are connected to the read word lines RWL, respectively. The other electrodes of the transistors RT2 are connected to the associated reference voltage line VUW. In the second embodiment, reference sign VUW is also used to denote a reference voltage source for a read operation and the line is referred to as "reference voltage line". The gates of the transistors RT2 are connected to an associated read main word line bRMWL. One electrode and the other electrode of each transistor RT2 can function as a source electrode or a drain electrode according to a voltage supplied to the transistor RT2.

Each read main word line bRMWL is connected in common to the gates of a plurality of transistors RT2 arrayed in the Z direction. A plurality of read main word lines bRMWL each extend in the Z direction and are arrayed in the Y direction. Each of the read main word lines bRMWL brings the corresponding transistors RT2 to the on-state and connects the reference voltage lines VUW to a plurality of read word lines RWL arrayed in the Z direction. The controller CTL can drive the read main word lines bRMWL independently of each other in accordance with addresses.

In the second embodiment, the read main word lines RMWL arrayed in the Y direction are not short-circuited and are electrically separated from each other. The controller CTL can drive the read main word lines RMWL independently of each other in accordance with addresses. The controller CTL selectively drives a pair of read main word lines RMWL and bRMWL located on both sides of the read word lines RWL of a selected row. The read main word line RMWL and the read main word line bRMWL transmit control signals of opposite logics. Therefore, when one of the transistors RT1 and RT2 is in the on-state, the other transistor is in the off-state. Accordingly, a read word line RWL selected at the time of reading is connected to the corresponding drive line WDRV and non-selected read word lines RWL are connected to the corresponding reference voltage lines VUW, respectively.

Other configurations of the second embodiment may be identical to those of the first embodiment.

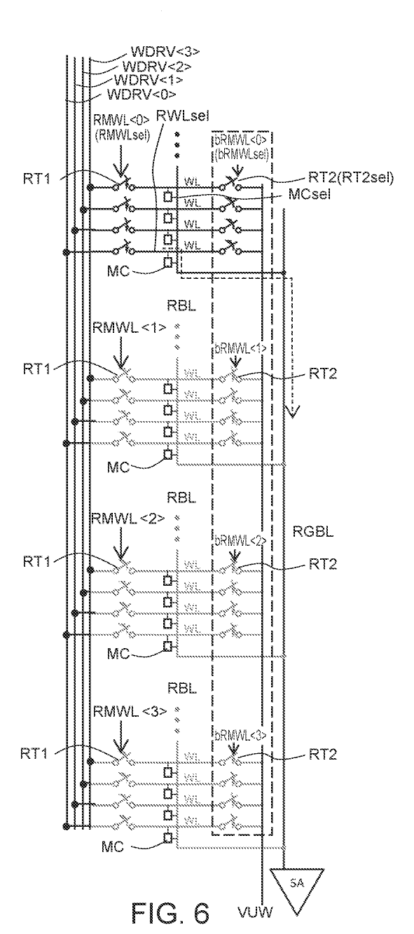

FIG. 6 is a conceptual diagram illustrating a read operation of the gain cell memory according to the second embodiment. A configuration related to one read global bit line RGBL associated with a read operation is extracted and illustrated in FIG. 6. Practically, a plurality of read global bit lines RGBL arrayed in the X direction simultaneously transmit data from memory cells MC corresponding thereto, respectively. The read operation is explained below with reference to FIGS. 5 and 6.

In the read operation, each of the read main word lines RMWL is caused to rise and a plurality of transistors RT1 sharing the read main word line RMWL are brought to the on-state. In the second embodiment, while each of the read main word lines RMWL is connected in common to the gates of a plurality of transistors RT1 arrayed in the Z direction, a plurality of read main word lines RMWL arrayed in the Y direction are electrically separated from each other. Each of the read main word lines bRMWL is also connected in common to the gates of a plurality of transistors RT2 arrayed in the Z direction while a plurality of read main word lines bRMWL arrayed in the Y direction are electrically separated from each other. Therefore, the controller CTL can selectively drive one of pairs of read main word lines RMWL and bRMWL extending in the Z direction. Each pair of the read main word lines RMWL and bRMWL are provided on both sides of the read word lines RWL arrayed in the Z direction and share these read word lines RWL.

The controller CTL selectively drives one drive line WDRV (for example, WDRV<0>) among the drive lines WDRV. Accordingly, one set (for example, the lowermost layer in FIG. 5) corresponding to the selected drive line WDRV<0> is selected. That is, a high-level voltage for read is applied up to the transistors RT1 in the lowermost layer connected to the drive line WDRV<0>.

As illustrated in FIG. 6, the controller CTL selectively drives, for example, a pair of read main word lines RMWL<0> and bRMWL<0>. That is, the read main word line RMWL<0> is caused to rise to bring the corresponding transistors RT1 to the on-state. The read main word line bRMWL<0> is caused to fall to bring the corresponding transistors RT2 to the off-state. Accordingly, a plurality of read word lines RWL between the pair of the read main word lines RMWL<0> and bRMWL<0> are selectively connected to the drive lines WDRV<0> to WDRV<3>, respectively. At this time, the selected drive line WDRV<0> transmits a high-level voltage for read and the other non-selected drive lines WDRV<1> to WDRV<3> transmit a low-level voltage for read pass. Accordingly, a selected read word line RWLsel connected to the drive line WDRV<0> among the read word lines RWL located between the pair of the read main word lines RMWL<0> and bRMWL<0> transmits the high-level voltage for read. Data in a selected memory cell MCsel connected to this selected read word line RWLsel is transmitted to the read global bit line RGBL through the read bit line RBL. The read operation is similarly performed in other columns and data transmitted to the read global bit line RGBL in each of the columns is detected by the sense amplifier SA corresponding thereto.

Meanwhile, the controller CTL causes, for example, read main word lines RMWL<1> to RMWL<3> to fall and causes read main word lines bRMWL<1> to bRMWL<3> to rise. Accordingly, a plurality of read word lines RWL located between the read main word lines RMWL<1> to RMWL<3> and bRMWL<1> to bRMWL<3> are connected to the corresponding reference voltage lines VUW, respectively, and are brought to the non-selected state.

As described above, in the second embodiment, the controller CTL selects one set (for example, the lowermost layer in FIG. 5) by selectively driving one drive line WDRV<0>. The controller CTL further selects one pair of the read main word lines RMWL<0> and bRMWL<0>. Accordingly, the transistors RT1 connected to one pair of the read main word lines RMWL<0> and bRMWL<0> are brought to the on-state to connect the drive lines WDRV<0> to WDRV<3> to the read word lines RWL corresponding to the read main word lines RMWL<0> and bRMWL<0>. The transistors RT2 connected to one pair of the read main word lines RMWL<0> and bRMWL<0> are maintained the off-state. As a result, one read word line RWL (in the lowermost layer) corresponding to the drive line WDRV<0> among the read word lines RWL corresponding to the pair of the read main word lines RMWL<0> and bRMWL<0> can be selectively driven. The read bit lines RBL corresponding to the selected one read word line RWL (in the lowermost layer) transmit data from memory cells MC to the read global bit lines RGBL corresponding thereto, respectively.

According to the second embodiment, the controller CTL drives the read main word lines RMWL arrayed in the Y direction independently of each other. Due to provision of the read main word lines bRMWL and the transistors RT2, a read pass voltage can be applied to read word lines RWL corresponding to non-selected pairs of read main word lines RMWL and bRMWL on the basis of selection of a read main word line bRMWL. Accordingly, transistors between a plurality of read bit lines RBL and the corresponding read global bit line RGBL can be omitted. A plurality of read bit lines RBL arrayed in the Y direction can be connected in common to one read global bit line RGBL.

Furthermore, according to the second embodiment, each of the drive lines WDRV are shared by the write word lines WWL and the read word lines RWL. Therefore, similarly to the first embodiment, power consumption can be decreased while the wiring is simplified.

### Third embodiment

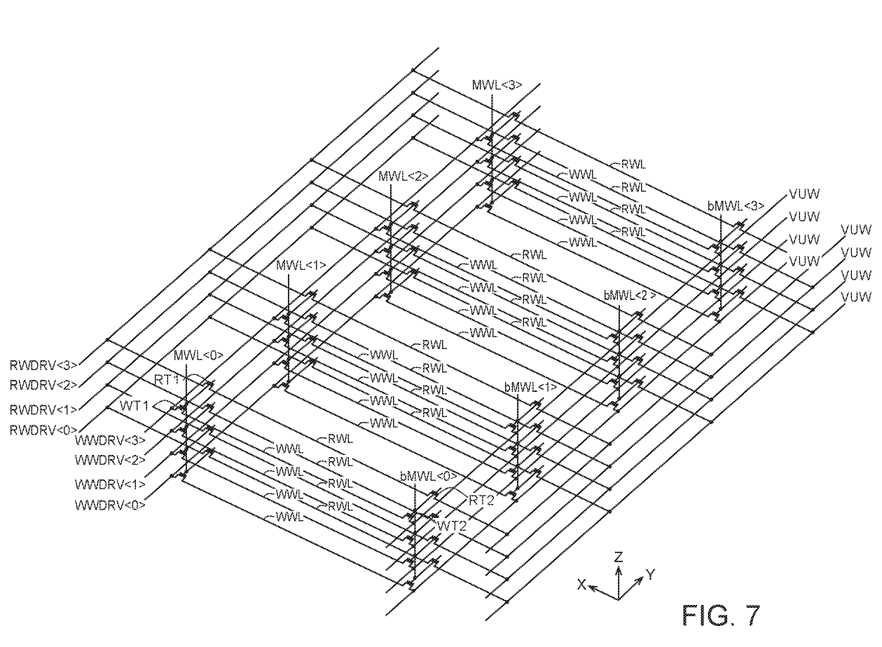

FIG. 7 is a perspective view illustrating a configuration example of a gain cell memory according to a third embodiment. In the first and second embodiments, the drive lines WDRV are shared by the configuration related to reading from the read word lines RWL and the like, and the configuration related to writing to the write word lines WWL and the like.

In contrast thereto, in the third embodiment, each main word line MWL is shared by the configuration related to reading from the read word lines RWL and the like, and the configuration related to writing to the write word lines WWL and the like. Each of drive lines is divided into a read drive line RWDRV and a write drive line WWDRV. Associated therewith, each of the reference voltage lines VUW may be divided into that for the configuration related to reading and that for the configuration related to writing. When the reference voltage is fixed, it is not particularly necessary to divide the reference voltage lines VUW.

The main word lines MWL extend in the Z direction and are arrayed in the Y direction. Each of the main word lines MWL is shared by a plurality of write word lines WWL and a plurality of read word lines RWL included in a plurality of sets (layers) arrayed in the Z direction. Therefore, each of the main word lines MWL is connected in common to the gates of a plurality of transistors WT1 and a plurality of transistors RT1 included in the sets (layers) arrayed in the Z direction.

The main word lines bMWL extend in the Z direction and are arrayed in the Y direction. Each of the main word lines bMWL is shared by the write word lines WWL and the read word lines RWL arrayed in the Z direction. Therefore, each of the main word lines bMWL is connected in common to the gates of a plurality of transistors WT2 and a plurality of transistors RT2 arrayed in the Z direction.

Accordingly, in a read operation and a write operation, the main word lines MWL and bMWL selectively bring the transistors WT1, the transistors RT1, the transistors WT2, and the transistors RT2 corresponding thereto to the on-state.

Meanwhile, each drive line is divided into the read drive line RWDRV and the write drive line WWDRV. Therefore, any of the read drive lines RWDRV is selectively driven in a read operation, and any of the write drive lines WWDRV is selectively driven in a write operation.

This enables the controller CTL to selectively drive one read word line RWL or one write word line WWL among the read word lines RWL and the write word lines WWL connected to selected main word lines MWL and bMWL. One read word line RWL can be selectively driven when any of the read drive lines RWDRV is selectively driven in a read operation. One write word line WWL can be selectively driven when any of the write drive lines WWDRV is selectively driven in a write operation.

While illustrations of a bit line configuration and arrangement of the memory cells MC are omitted in FIG. 7, the bit line configuration and the arrangement of the memory cells MC may be the same as those illustrated in FIG. 5. Transistors between the read bit lines RBL and the associated read global bit line RGBL can be omitted. Furthermore, a plurality of read bit lines RBL arrayed in the Y direction can be connected in common to one read global bit line RGBL. Meanwhile, transistors between the write bit lines WBL and the associated write global bit line WGBL can be omitted. Furthermore, a plurality of write bit lines WBL arrayed in the Y direction can be connected in common to one write global bit line WGBL. Accordingly, data in memory cells MC of a plurality of columns connected to a selected read word line RWL are transmitted to the read global bit lines RGBL of the corresponding columns. Alternatively, data from write global bit lines WGBL are transmitted to memory cells MC of columns connected to a selected write word line WWL.

In the third embodiment, the transistors RT2 and the reference voltage lines VUW connected to the read word lines RWL may be omitted similarly to the first embodiment while each of the main word lines MWL is shared by the configuration related to reading and the configuration related to writing. In this case, it suffices that the bit lines are configured in the same manner as the bit line configuration illustrated in FIG. 2. That is, transistors are provided between a plurality of read bit lines RBL and the associated read global bit line RGBL, respectively. Transistors are also provided between a plurality of write bit lines WBL and the associated write global bit line WGBL, respectively.

According to the third embodiment, each of the main word lines MWL is shared by the configuration related to reading and the configuration related to writing. Accordingly, the wiring can be simplified while the normal operation is maintained.

### Fourth embodiment

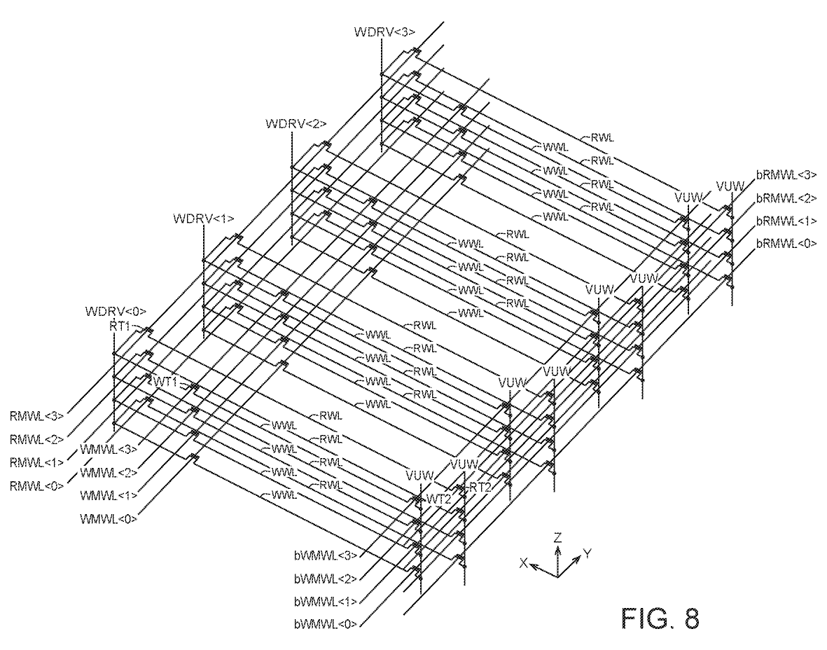

FIG. 8 is a perspective view illustrating a configuration example of a gain cell memory according to a fourth embodiment. In the fourth embodiment, the read main word lines RMWL and bRMWL and the write main word lines WMWL and bWMWL extend in the Y direction and are arrayed in the Z direction. Each read main word line RMWL is connected in common to the gates of a plurality of transistors RT1 arrayed in the Y direction. Each write main word line WMWL is connected in common to the gates of a plurality of transistors WT1 arrayed in the Y direction. The controller CTL selects one set (layer) by selectively driving read main word lines RMWL and bRMWL or write main word lines WMWL and bWMWL.

Meanwhile, the drive lines WDRV extend in the Z direction and are arrayed in the Y direction. Each drive line WDRV is provided in common to a plurality of write word lines WWL and a plurality of read word lines RWL arrayed in the Z direction. Associated therewith, the reference voltage lines VUW also extend in the Z direction and are arrayed in the Y direction. Each of the reference voltage lines VUW is provided in common to the write word lines WWL or the read word lines RWL arrayed in the Z direction. Each reference voltage line VUW may be divided into that for the configuration related to reading and that for the configuration related to writing. It is not particularly necessary to divide the reference voltage lines VUW when the reference voltage is fixed.

In the fourth embodiment, the relation in the extending direction between the main word lines RMWL, bRMWL, WMWL, and bWMWL, and the drive lines WDRV and the reference voltage lines VUW is the opposite to the relation in the extending direction of those in the second embodiment.

Therefore, in a read operation, the controller CTL selectively drives one read main word line RMWL (for example, RMWL<0> from the read main word lines RMWL. Accordingly, one set (for example, the lowermost layer in FIG. 8) corresponding to the selected read main word line RMWL<0> is selected. That is, the transistors RT1 in the lowermost layer connected to the read main word line RMWL<0> are brought to the on-state and the drive lines WDRV<0> to WDRV<3> are connected to the read word lines RWL in the lowermost layer, respectively. At this time, for example, when the drive line WDRV<0> transmits a high-level voltage for read, the high-level voltage for read is selectively applied to one read word line RWL connected to the drive line WDRV<0> among the read word lines RWL in the lowermost layer.

While illustrations of the bit line configuration and arrangement of the memory cells MC are omitted in FIG. 8, the bit line configuration and the arrangement of the memory cells MC may be the same as those illustrated in FIG. 5. Transistors between the read bit lines RBL and the associated read global bit line RGBL can be omitted. Furthermore, a plurality of read bit lines RBL arrayed in the Y direction can be connected in common to one read global bit line RGBL. Accordingly, data in memory cells MC of a plurality of columns connected to a selected read word line RWL are transmitted to the read global bit lines RGBL of the corresponding columns.

Also in a write operation, a write word line WWL, write bit lines WBL, and selected memory cells MC are selected in the same manner as in the read operation. Therefore, transistors between the write bit lines WBL and the associated write global bit line WGBL can be omitted. A plurality of write bit lines WBL arrayed in the Y direction can be connected in common to one write global bit line WGBL. Accordingly, data from write global bit lines WGBL are transmitted to memory cells MC of columns connected to a selected write word line WWL.

Other configurations of the fourth embodiment may be identical to those of the second embodiment.

In the fourth embodiment, the transistors RT2 and the reference voltage lines VUW connected to the read word lines RWL can be omitted similarly to the first embodiment while each of the drive lines WDRV is shared by the write word lines WWL and the read word lines RWL. That is, the read word lines RWL may be separated from the reference voltage lines VUW. In this case, it suffices that the bit lines are configured in the same manner as the bit line configuration illustrated in FIG. 2. That is, transistors are provided between a plurality of read bit lines RBL and the associated read global bit line RGBL, respectively. Transistors are also provided between a plurality of write bit lines WBL and the associated write global bit line WGBL, respectively.

According to the fourth embodiment, each of the main word lines is divided into the read main word line RMWL and the write main word line WMWL. Meanwhile, each of the drive lines WDRV is shared by the configuration related to reading and the configuration related to writing. Accordingly, the wiring can be simplified while the normal operation is maintained.

### Fifth embodiment

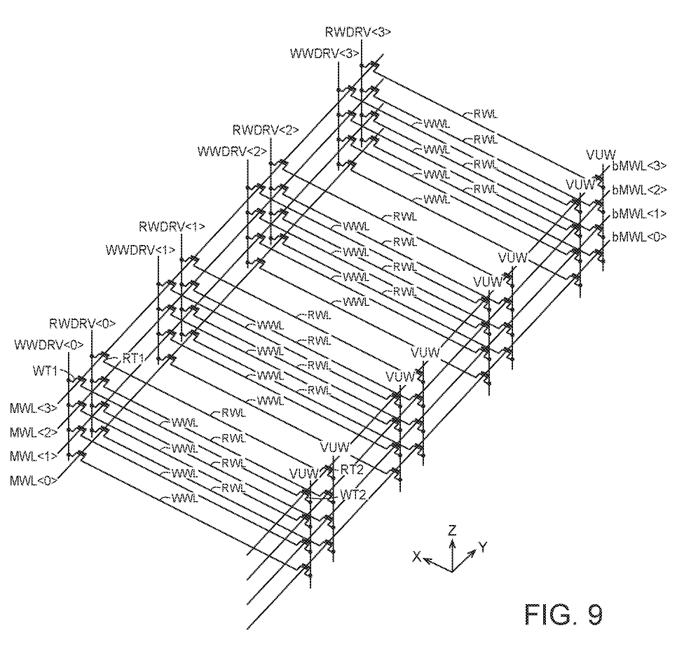

FIG. 9 is a perspective view illustrating a configuration example of a gain cell memory according to a fifth embodiment. In the fifth embodiment, each of the main word lines MWL is shared by the configuration related to reading from the read word lines RWL and the like and the configuration related to writing to the write word lines WWL and the like. Each of the drive lines is divided to the read drive line RWDRV and the write drive line WWDRV. Associated therewith, each of the reference voltage lines VUW may be divided to that for the configuration related to reading and that for the configuration related to writing. It is not particularly necessary to divide the reference voltage lines VUW when the reference voltage is fixed.

The main word lines MWL extend in the Y direction and are arrayed in the Z direction. Each main word line MWL is shared by a plurality of write word lines WWL and a plurality of read word lines RWL arrayed in the Y direction. Therefore, each main word line MWL is connected in common to the gates of a plurality of transistors WT1 and a plurality of transistors RT1 arrayed in the Y direction.

The main word lines bMWL extend in the Y direction and are arrayed in the Z direction. Each main word line bMWL is shared by the write word lines WWL and the read word lines RWL arrayed in the Y direction. Therefore, each main word line bMWL is connected in common to the gates of a plurality of transistors WT2 and a plurality of transistors RT2 arrayed in the Y direction.

Accordingly, in a read operation and a write operation, the main word lines MWL and bMWL selectively bring the corresponding transistors WT1, RT1, WT2, and RT2 to the on-state.

Meanwhile, each drive line is divided into the read drive line RWDRV and the write drive line WWDRV. Therefore, any of the read drive lines RWDRV is selectively driven in a read operation, and any of the write drive lines WWDRV is selectively driven in a write operation. Each of the read drive lines RWDRV is shared by a plurality of read word lines RWL arrayed in the Z direction. Each of the write drive lines WWDRV is shared by a plurality of write word lines WWL arrayed in the Z direction.

This enables the controller CTL to selectively drive one read word line RWL or one write word line WWL among the read word lines RWL and the write word lines WWL connected to selected main word lines MWL and bMWL. One read word line RWL can be selectively driven when any of the read drive lines RWDRV is selectively driven in a read operation. One write word line WWL can be selectively driven when any of the write drive lines WWDRV is selectively driven in a write operation.

While illustrations of a bit line configuration and arrangement of the memory cells MC are omitted in FIG. 9, the bit line configuration and the arrangement of the memory cells MC may be the same as those illustrated in FIG. 5. Transistors between the read bit lines RBL and the associated read global bit line RGBL can be omitted. Furthermore, a plurality of read bit lines RBL arrayed in the Y direction can be connected in common to one read global bit line RGBL. Meanwhile, transistors between the write bit lines WBL and the associated write global bit line WGBL can be omitted. Furthermore, a plurality of write bit lines WBL arrayed in the Y direction can be connected in common to one write global bit line WGBL. Accordingly, data in memory cells MC in a plurality of columns connected to a selected read word line RWL are transmitted to the read global bit lines RGBL of the corresponding columns. Alternatively, data from write global bit lines WGBL are transmitted to memory cells MC of columns connected to a selected write word line WWL.

In the fifth embodiment, the transistors RT2 and the reference voltage lines VUW connected to the read word lines RWL may be omitted similarly to the first embodiment while each of the read drive lines RWDRV is shared by a plurality of read word lines RWL and each of the write drive lines WWDRV is shared by a plurality of write word lines WWL. That is, the read word lines RWL may be separated from the corresponding reference voltage line VUW. In this case, it suffices that the bit lines are configured in the same manner as the bit line configuration illustrated in FIG. 2. That is, transistors are provided between a plurality of read bit lines RBL and the associated read global bit line RGBL, respectively. Furthermore, transistors are provided between a plurality of write bit lines WBL and the associated write global bit line WGBL, respectively.

Other configurations of the fifth embodiment may be identical to those of the fourth embodiment. Therefore, the fifth embodiment can obtain effects identical to those of the fourth embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising:
a plurality of first data lines and a plurality of first control lines to be used for writing of data;
a plurality of second data lines and a plurality of second control lines to be used for reading of data;
a plurality of memory cells each comprising a first transistor having a gate connected to any of the first control lines and one end connected to any of the first data lines, a second transistor having a gate connected to any of the second control lines and one end connected to any of the second data lines, and a third transistor having a gate connected to the other end of the first transistor to retain data from the first data line and one end connected to the other end of the second transistor, the third transistor being brought to a conduction state according to the data;
a first drive line provided in common to the first control lines and the second control lines and configured to transmit a selection voltage for performing writing of data;
a plurality of fourth transistors connected between the first control lines and the first drive line;
a plurality of fifth transistors connected between the second control lines and the first drive line;
a plurality of third control lines connected to gates of the fourth transistors, respectively; and
a plurality of fourth control lines connected to gates of the fifth transistors, respectively.

2. The device of claim 1, wherein
assuming the first control lines, the second control lines, and the memory cells corresponding to the first drive line as one set,
one of the third control lines is connected in common to gates of the fourth transistors corresponding to a plurality of the sets, and
one of the fourth control lines is connected in common to gates of the fifth transistors corresponding to the sets.

3. The device of claim 2, wherein
one of the third control lines is provided in common to the first control lines corresponding to the sets, and
one of the fourth control lines is provided in common to the second control lines corresponding to the sets.

4. The device of claim 1, wherein
the third control lines and the fourth control lines extend in a first direction in which the first and second data lines extend, and
the first drive line extends in a third direction intersecting with a second direction in which the first and second control lines extend and the first direction.

5. The device of claim 2, further comprising:
a fourth data line provided in common to the second data lines; and
a plurality of sixth transistors connected between the second data lines and the fourth data line.

6. The device of claim 5, further comprising:
a second drive line provided in common to the first control lines and configured to transmit a non-selection voltage for not performing writing of data; and
a plurality of seventh transistors connected between the first control lines and the second drive line, wherein
the second control lines are separated from the second drive line.

7. The device of claim 2, wherein
the third control lines are driven independently of each other, and
the fourth control lines are driven concurrently.

8. The device of claim 6, wherein
one of a plurality of the first drive lines selects a set from the plurality of the sets,
the second data lines transmit data from the memory cells in the selected set, respectively, and
the plurality of the sixth transistors corresponding to one of the second control lines in the selected set transmit data from the second data lines to a plurality of the fourth data lines corresponding to the sixth transistors, respectively.

9. The device of claim 2, further comprising a fourth data line connected in common to the second data lines, wherein
transistors are not provided between the second data lines and the fourth data line.

10. The device of claim 9, further comprising:
a second drive line provided in common to the first control lines and the second control lines and configured to transmit a non-selection voltage for not performing writing of data;
a plurality of seventh transistors connected between the first control lines and the second drive line; and
a plurality of eighth transistors connected between the second control lines and the second drive line.

11. The device of claim 10, wherein
one of a plurality of the first drive lines selects a set from the plurality of the sets,
the fifth transistor corresponding to one of the second control lines in the selected set connects the first drive line to the second control line, and
second data lines corresponding to one of the second control lines in the selected set transmit data from the memory cells to a plurality of the fourth data lines corresponding thereto, respectively.

12. The device of claim 1, wherein
the third control lines and the fourth control lines extend in a third direction intersecting with a first direction in which the first and second data lines extend and a second direction in which the first and second control lines extend, and
the first drive line extends in the first direction.

13. The device of claim 2, further comprising:
a third data line provided in common to the first data lines; and
a plurality of ninth transistors connected between the first data lines and the third data line.

14. A semiconductor storage device comprising:
a plurality of first data lines and a plurality of first control lines to be used for writing of data;
a plurality of second data lines and a plurality of second control lines to be used for reading of data;
a plurality of memory cells each comprising a first transistor having a gate connected to any of the first control lines and one end connected to any of the first data lines, a second transistor having a gate connected to any of the second control lines and one end connected to any of the second data lines, and a third transistor having a gate connected to the other end of the first transistor to retain data from the first data line and one end connected to the other end of the second transistor, the third transistor being brought to a conduction state according to the data;
a third control line provided in common to the first control lines and the second control lines;
a plurality of first drive lines each corresponding to a part of the first control lines;
a plurality of second drive lines each corresponding to a part of the second control lines;
a plurality of fourth transistors connected between the first drive lines and the first control lines, respectively, and having gates connected in common to the third control line; and
a plurality of fifth transistors connected between the second drive lines and the second control lines, respectively, and having gates connected in common to the third control line.

15. The device of claim 14, wherein
assuming the first control lines, the second control lines, and the memory cells corresponding to one of the first drive lines as one set,
one of the third control lines is connected in common to gates of the fourth transistors and gates of the fifth transistors corresponding to a plurality of the sets.

16. The device of claim 15, wherein one of the third control lines is provided in common to the first control lines and the second control lines corresponding to the sets.

17. The device of claim 14, wherein
the third control lines extend in a third direction intersecting with a first direction in which the first and second data lines extend and a second direction in which the first and second control lines extend, and
the first drive lines and the second drive lines extend in the first direction.
